(19) United States
(12) Patent Application Publication
(10) Pub. No.: US 2006/0027933 A1
(43) Pub. Date: Feb. 9, 2006

(54) Process for protecting solder joints and structure for alleviating electromigration and joule heating in solder joints

(76) Inventors: Chih Chen, Dadu Township (TW); Everett Chang-Ching Yeh, Houlong Township (TW); King-Ning Tu, Los Angeles, CA (US)

Correspondence Address: BUCKNAM AND ARCHER, 1077 NORTHERN BOULEVARD, ROSLYN, NY, 11576, US

(21) Appl. No.: 11/068,255

(22) Filed: Feb. 28, 2005

(30) Foreign Application Priority Data
Aug. 4, 2004 (TW) 93123344

(51) Int. Cl. H01L 23/48

(52) U.S. Cl. 257/772

(57) ABSTRACT

This invention provides a process for protecting solder joints, comprising forming an UBM or pad metallurgy in solder joints and then further forming a small solder bump on UBM or pad metallurgy between substrate and chip. Wherein a material of high electric resistance is coated at the ends of UBM or pad metallurgy where substrate is connected to chip, as to equalize the current distribution of solder bump, therefore the electromigration resistance of solder joints is improved by suppressing the current crowding and joule heating phenomenon.

### FIELD OF THE INVENTION

The present invention provides a designing process for protecting joints including flip-chip solder joints, anisotropic conductive film (ACF) or tape automatic bond (TAB) joints, etc., in electronic packaging industry. The present invention alleviates current crowding effect of the solder bump and the electromigration damage, to prolong the life-time of the above joints. Current crowding results in local high current density region and causes local joule heating in solder joints. By suppressing the current crowding and joule heating phenomenon, the electromigration resistance of solder joints is improved and consequently the reliability of solder joints is enhanced. By suppressing current crowding, current flow paths are redistributed and become more uniform through a solder joint. Therefore, the current carrying capacity of each solder ball is increased and its effective resistance could be reduced under proper design.

The present invention is widely applicable to a variety of electronic products including computers, communication equipments, automobiles, consumer electronics, and liquid crystal displays.

### DESCRIPTION OF THE RELATED ART

The current trend in electronic package is a wider application of flip chip technology to microprocessors and consumer products. The technology uses area array of solder bumps to attach chips directly to organic modules. It is a low cost packaging for movable and wireless electronic consumer products. The size of these solder bumps is quite small because a large number of them is needed as chip-to-package interconnects. As the wireless hand-held devices become more functional, smaller chip-to-package interconnects are necessary. Serious reliability problems arise with respect to thermal-mechanical fatigue, heat dissipation, and electromigration in these small solder bumps. Concerning electromigration, at the moment the device design rule requires each solder bump to carry 0.2 Amp and to extend to 0.4 Amp in the near future. For solder bumps of 50 μm in diameter, the current density will reach 10⁴ A/cm². Since solder is a low melting point alloy having a fast atomic diffusion at ambient temperature, electromigration is a serious reliability concern. Indeed, it has been shown that electromigration occurs within a few hundred hours in eutectic SnPb solder joints kept at 150° C. under a current density of 8×10³ A/cm². Besides the eutectic alloy, electromigration in Pb-free solder joints has also been reported.

The flip-chip technology used in packaging industry mainly comprises producing metallic bumps (or termed as solder bumps) on chip I/O pads as medium for substrate jointing; The input/output (I/O) pin count of flip chip products has dramatically increased recently to meet the required high performance. In addition, bump pitch has decreased rapidly, so, the contact area of the solder bumps and the diameter of under bump metallization (UBM) continuous to shrinking. Therefore, electromigration (EM) of the solder bumps has become an important issue.

The so-called “electromigration” is the phenomenon that atoms inside materials migrate due to the effects of electric fields and charged carriers. Taking aluminum atoms 1 as an example, which is shown in FIG. 1, the Al atoms are moved from their original location to saddle point then to vacancy when hit by charged carriers, under the effect that the generated momentum is transferred; the electromigration of pure metal can be represented by the following mathematical formula:
F=Z*eE=(Z*el+Z*wd)eE
Namely, force eE is applied to electrons under the effect of electric filed E, and Z*eE to ions; in which Z*el is the nominal atomic valence of the diffused atoms (coulomb force of metal ions under electric filed), Z*wd is the effective charging number of electron (which is originated from the momentum transfer between electrons and metal ions); when Z*wd>Z*el, they move toward the moving direction of the electrons. For metals, Z*wd is far larger than Z*el.

In addition, when additional current (I) passes the metal (with resistance R), the metal is heated to higher temperature, i.e., Joule heating effect, so that the diffusion coefficient becomes larger, resulting in more serious electromigration; therefore, electromigration is a phenomenon that atoms transport due to the combination the electric and heating effects. Moreover, in terms of flip-chip joints, the current crowding effect is generated at the joints of the solder and the conducting line due to their specific geometric shape (shown in FIG. 2), so that reliability problem arises since the above effect damage the joints of solders and the conducting line.

With the trend to use less Pb due to environmental concerns, tin is becoming the main component of solders; in addition, lead frame may become short due to the tin whisker growth in tin-finished layer, so that the electromigration of pure tin also relates to reliability problem in Pb-free solders.

Conventional technology focused on the improvements of some performance parameters, for example, stress problems caused by the heat diffusion or expansion coefficient difference between IC chips and substrate materials. These improvements comprises the optimization of solder bumps, the change of solder chemical composition, or the way to fill organic resin materials into gaps in solder joints, which are ineffective and do not solve the problems of the electromigration, Joule heating effect and thermal expansion material stress caused by joints after miniaturization of high-end electronic products. For example, U.S. Pat. No. 6,593,649 discloses a process to decrease lead connection distance in order to control electric performance parameters by changing I/O pad layout, but fails to improve the drawback that joint life is obviously reduced due to containing more I/O joints. Therefore, the present process for protecting flip-chip solder joints has never been reported in the field of present technology and related documents, the following discussion achieved by Inventor is a novel concept and means to the conventional technology.

To improve the electromigration resistance in solder bumps, efforts have been devoted in finding better solder alloys which have slower atom diffusion velocity. As far as we know, no efforts have been invented in designing current distribution of solder joints to improve their electromigration resistance and current carrying capacity. In other words, our invention is based on electrical properties of the solder joint.

### SUMMARY OF THE INVENTION

Flip-chip technology is currently widely applied to package operation in high-end electronic products. In the present circuit designs, the current applied to each solder bump joint is 0.2 A (and is to be increased up to 0.4 A), and the size of solder bump is to be miniaturized from 100 μm to 50 μm in diameter, then the current density will be up to 10⁴ A/cm². Under the elemental operation temperature of 100° C., the electromigration will occurs in solders due to lattice diffusion.

In order to relieve electromigration damage, the present process protects flip-chip solder joints, joints of anisotropic conductive film (ACF), and joints of tap automatic bond (TAB) by adding a thin layer of high electric resistivity materials in UBM of the chip side or in the pad metallurgy in the substrate side. This resistive layer can alleviate current crowding effect, and thus can suppress electromigration damage and thermal damage due to Joule heating effect. Therefore, the life time of the joints can be prolonged.

As described above, the present flip-chip solder bump structure comprises a very thin layer of high electric resistance material, such as TaN, TiN, or oxide.

### A BRIEF DESCRIPTION OF THE DRAWINGS

FIG. 1 is a schematic showing the movement of atoms inside the materials by the effect of electric fields and charged carriers;

FIG. 2 is a schematic showing the geometry of the solder joints;

FIG. 3 is a cross-sectional view of the flip-chip solder joints used in the present invention;

FIG. 4 is a scanning electronic microscope (SEM) image showing solder bump after different stressing time (0 hour, 20 hours, 264 hours, 408 hours) under the current density of 20,000 A/cm² at 100° C.;

FIG. 5 is a SEM image showing the failure of a solder bump under the current density of 10,000 A/cm² at 150° C.;

FIG. 6 is a SEM image showing the electromigration failure at the anode/chip end of the solder bump after the selective etching of Sn;

FIG. 7 shows the three-dimensional distribution of the current density in the solder bump simulated by finite element analysis;

FIG. 8 shows the current density distribution in the cross-section along the Z-axis of the solder bump in FIG. 7;

FIG. 9(a)˜(e) shows the current density distribution when adopting or inserting a thin highly resistantiveive UBM layer. (29.54 μΩ·cm, 295.4 μΩ·cm, 1477 μΩ·cm, 2954 μΩ·cm, 1477 μΩ·cm); the current density distribution in the top layer of the solder became more uniform as the UBM resistivityanceivity increased;

FIG. 10 shows the current density distribution inside the top layer of the solder along the Z-axis in FIG. 9(a)˜(e);

FIG. 11 is a schematic showing the IR apparatus for temperature measurement used in the present invention;

FIG. 12 shows the temperature measurement during current stressing by 0.586 A on a stage kept at 70°;

FIG. 13 shows the temperature gradient of the solder bump, +365° C./cm;

FIG. 14 shows an elevation and a side view of the pure tin test sheet used in the present invention;

FIG. 15 is a SEM image showing tin whiskers and protrusions created at anode side after current stressing at different time periods; and

FIG. 16 depicts the volume of tin whiskers vs. stressing time. The growth rate of the tin whiskers was about 3 Å/sec.

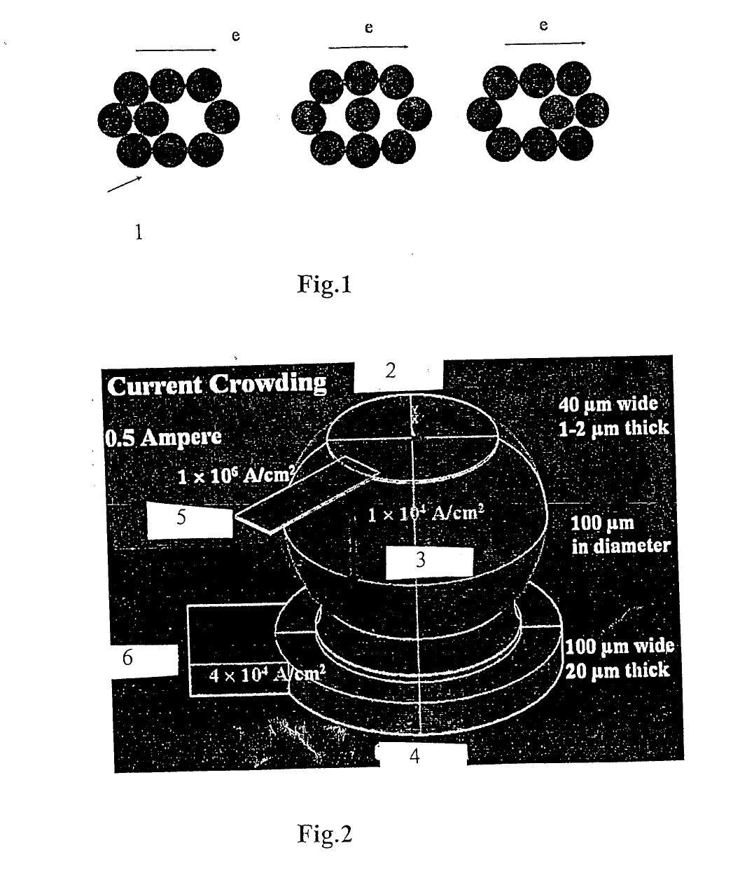

### DETAILED DESCRIPTION OF THE INVENTION

The present invention relates to a process for protecting solder bumps from electromigration damage. With the trend to use lead-free solders, tin is becoming the main component of the solders; in addition, lead frame may short-circuit due to the tin whisker growth. Therefore, electromigration has become an important reliability subject in lead-free solders.

Another goal of the present invention is to provide a novel structure for flip-chip solder joints, obtained from the above-described process for protecting solder joints, applicable to a variety of electronic products including computers, communication equipments, automobiles, consumer electronics, and liquid crystal displays and the like, to alleviate the problems created by electromigration in addition to the embodiments of the present invention.

There are three modes relating to electromigration damage of general solder bumps:
1. Due to the specific geometric shape of the solder bump (shown in FIG. 2) and the resistance difference between aluminum lead and bump, the averaged current density of aluminum lead and bump are 1×10⁷ and 1×10⁴ A/cm² respectively when applied a current of 0.5 A; the resistance is 180 mΩ for aluminum lead and 8 mΩ for bump. The resistance difference between the two prevents current flowing through the whole lead/bump contact window uniformly but to crowd on one edge of the contact window due to its the least resistive path for current flow—the so-called current crowding effect. When current crowding occurs, the local current density at the crowding site could be a order of magnitude higher than the average current density. This effect, therefore, accelerates the electromigration damage of the joints between aluminum lead and solder bump.
2. In addition to the non-uniform current density distribution, the temperature distribution in such system is also non-uniform. Joule heating resulted from the resistive lead/bump modifies the local temperature. More joule heating occurs in aluminum lead, so that a temperature gradient is created in the solder bump, which further promotes the occurrence of electromigration, and create secondary damage on solder bump. Consequently, the actual temperature of the sold bump is higher than as predetermined, so the damage time (or the mean-time-to-failure) of the solder bump is shortened. For scalable electromigration design rules, it is necessary to calibrate the temperature while applying current.
3. Another cause of solder bump ineffectiveness is that the cupper and nickel atoms inside UBM or pad metallurgy of substrate will migrate into solder bump under the effect of electron flow. The electromigration enhanced reaction between UBM and solder bump results in the accumulation of dielectric metal compounds Cu₆Sn₅ or Ni₃Sn4. Such compound accumulation increases the stresses and consequently leads to higher probability of creating damages.
   In order to avoid the creation of the above described electromigration, the present process for protecting solder joints comprises, in flip-chip solder joints, joints on anisotropic conductive film (ACF) or tap automatic bond (TAB) in electronic package operation, adding high electric resistance material at the locations connecting UBM or pad metallurgy and chip or substrate, to alleviate current concentration, further to suppress electromigration damage and thermal damage of Joule heating effect, so that to prolong service life of the joints.

In terms of package joints, joint materials (solder) mainly comprise solder, gold, gold stud, polymer, indium, gold tin and the like, and in consideration of the adhesiveness and conductivity of the joints include UBM or pad metallurgy, which is generally selected from solder- or process-compatible materials, for example, chromium, cupper, nickel, gold and the like. However, the high electric resistance material used as the above-described chip end or substrate end can be a very thin layer of pure materials (such as molybdenum), oxides (such as SiO₂ and Si₃N₄), or metal oxides (such as Al₂O₃), nitrides (such as TiN and TaN) with high electric resistance. (Everett's note: not getting the message from this paragraph)

UBM or Pad metallurgy is positioned between chip end pad metallurgy and metal bumps to provide the functions of connection and prevention of inter-diffusion between UBM or pad metallurgy and metal bumps. The production processes of UBM or Pad metallurgy mainly comprise vapor deposition, sputter deposition, and electroless plating of nickel/gold and the like; and the production processes of bump comprise vapor deposition, electroplating, steel plate (or resist dry film) printing, and ball array and the like; gold bump is produced by electroplating. The production processes of UBM or Pad metallurgy, and a very thin layer of high electric resistance materials in the present invention comprise electroplating, physical vapor deposition, chemical vapor deposition, or atomic layer chemical vapor deposition.

Obtained from the above-described process for protecting flip-chip solder joints, the present flip-chip solder structure comprises a very thin layer of high electric resistance material like oxide or TiN at the ends of UBM between chip and substrate connected by bumps.

### Embodiment

The present embodiments include electromigration studies made through the following limited elemental analysis, IR temperature detection analysis, and actual solder bumps, however, the concepts and claims of the present invention are not limited thereto.

1. General Solder Production and Reliability

A current of 0.5 A was applied to solder bump 3 with the specific geometric shape shown in FIG. 2, the current density of aluminum lead and bump were 1×10⁷ and 1×10⁴ A/cm² respectively, further, the resistance was 180 mΩ for aluminum lead 5 and 8 mΩ for bump 3. The resistance differences and the specific geometric shape enabled the majority of electrons moving toward the left side of the bump 3 then flowing down, and accelerated the damage of the joints between aluminum lead 5 and solder bump 3. In addition, Joule heating effect was larger in aluminum lead 5, thus temperature gradient was created in solder bump 3 to further promote the occurrence of electromigration, and created another solder bump damage mode. Moreover, cupper and nickel atoms 6 inside UBM or pad metallurgy of substrate 4 migrated into solder bump 3 under the effect of electron flow, reacted between UBM and solder bump 3 to result the accumulation of transitional metal compounds Cu₆Sn₅ or Ni₃Sn4, so that stresses were created to damage. (Everett's note: please revise this section with the previous revisions accordingly.)

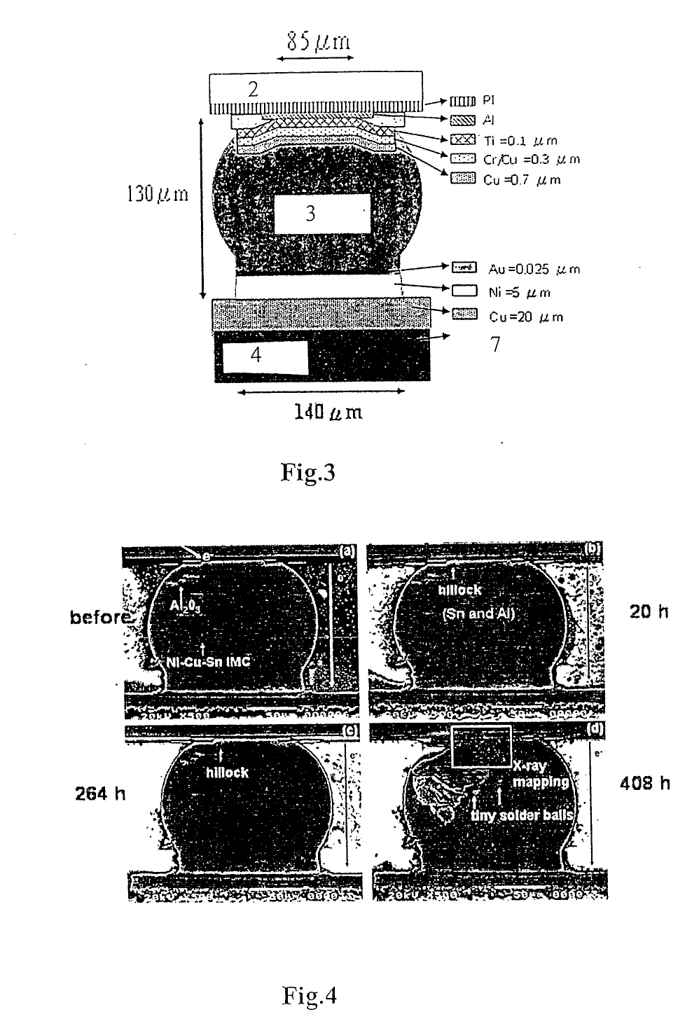

FIG. 3 is a cross-sectional view of the flip-chip solder joints used in the present invention. The UBM composition used at chip 2 end was: Ti: 0.1 μm, phase-in Cr—Cu: 0.3 μm, and Cu: 0.7 μm; and that used at substrate end was: Au: 0.025 μm, Ni: 5 μm, and Cu: 20 μm. The diameter of solder bump 3 was generally 100 μm, while that of the contact area between solder bump of chip 2 end and UBM was about 85 μm (the current density in this invention is estimated based on the contact area between solder bump 3 and UBM), wherein the diameter of the contact area between solder bump 3 of substrate end and UBM was about 100 μm. Electron flow entered from the left-front side of the chip 2 end, traveled through solder bump 3 and flew out at the left of substrate 4 end, as shown in the three-dimensional scheme of FIG. 2.

FIG. 4 are scanning electronic microscopic images showing solder bump after different time periods (0 hour, 20 hours, 264 hours, 408 hours) under current density of 20,000 A/cm² and temperature of 100° C. It can be found from this figure that, the damage was created at the solder bump where the chip end lead entered; and it can be found that small tin balls distributed at the surface of the solder bump. It is proved that when the solder bump is damaged at the location the chip end lead enters, the temperature is as high as the melting point of the solder bump itself. With current analysis and temperature detection analysis, it is known that, at the solder bump where the chip end lead entered, current crowding and joule heating occur and accelerate electron migration and heat migration damage. Reliability degradation of the solder bump is speeded up under the dual effects.

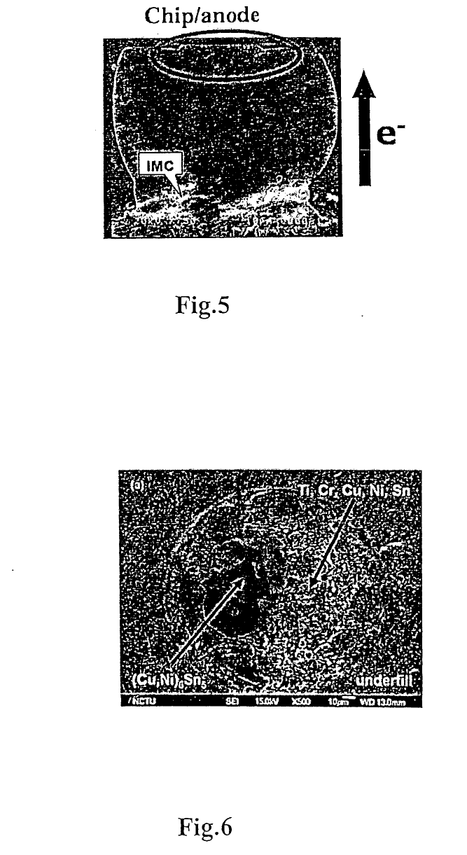

FIG. 5 is a scanning electronic microscopic image showing the ineffective condition of anode chip due to damage under current density of 10,000 A/cm² and temperature of 150° C. (Everett's note: ineffective condition means?)

FIG. 6 is a scanning electronic microscopic image showing the anode chip end of the ineffective solder bump after selective etching by etch solution. It can be found that a large amount of transitional metal (Cu, Ni)₆Sn₅ accumulated at the interface between UBM or pad metallurgy, and it is assumed that this phenomenon resulted stress to create slits on the solder bump at said interface and damaged.

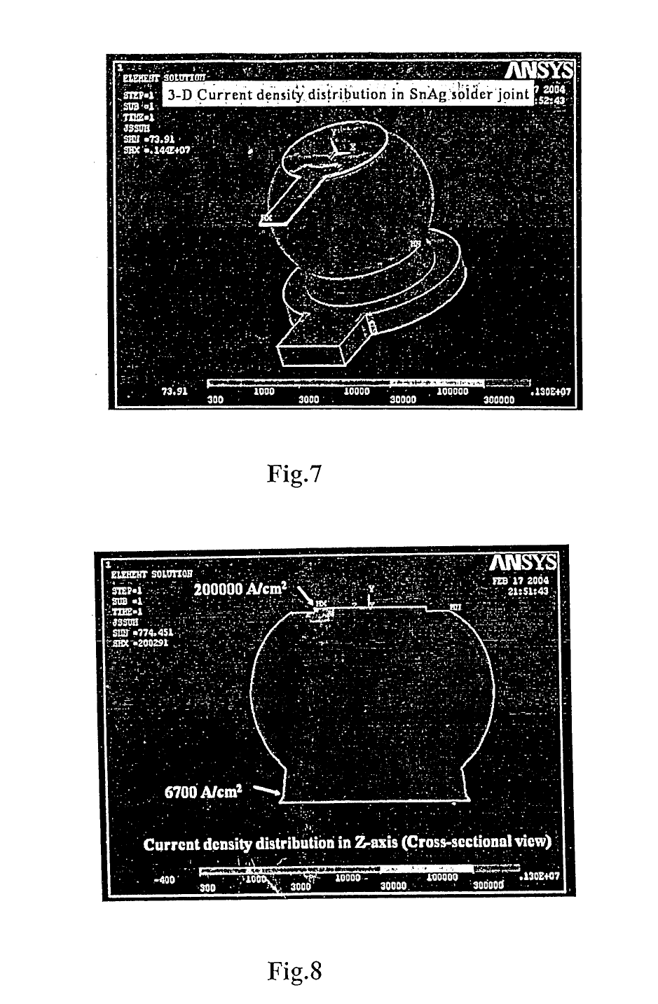

FIG. 7 is a view showing the three-dimensional distribution of the current in the solder bump analyzed by limited elemental analysis. It can be found from the analysis results that, the highest current density is located at the contact between solder bump of chip end and aluminum lead.

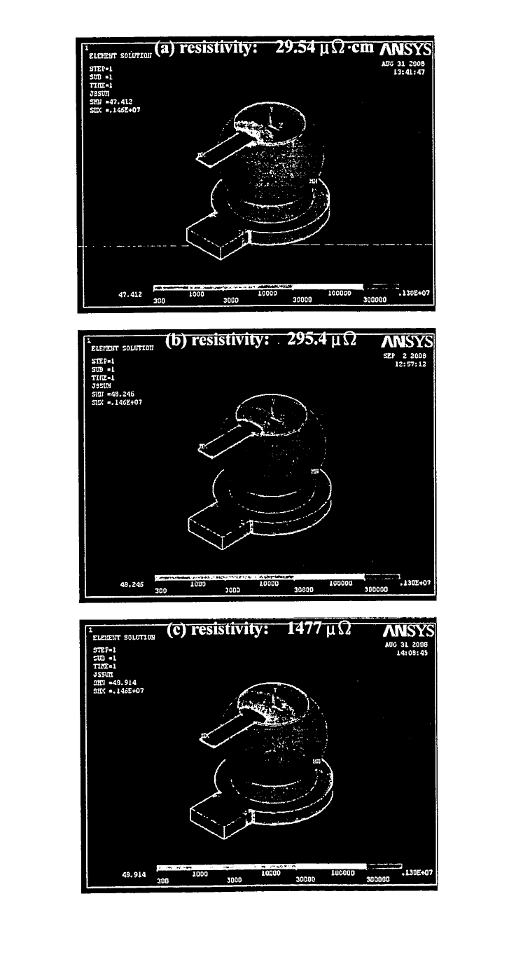

A further cross-sectional current density analysis is shown in FIG. 8. As shown, the current density is up to 20,000 A/cm² at the contact between aluminum lead of chip end and UMB, and the average current density inside the solder bump is about 5,000 A/cm², a 40-fold difference. Due to the current crowding effect, when the major part of electron flow traveling aluminum lead entered into bump, they concentrated, as the least resistive path suggested, and flew into solder bump, which resulted in the most easiest damage point of the solder bump.

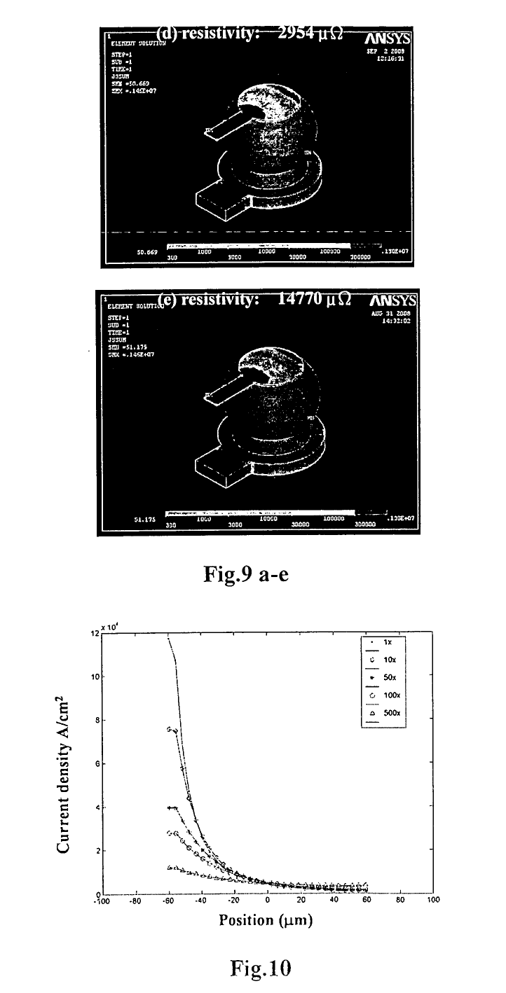

FIG. 9(a)˜(e) shows the current density distribution when adopting or inserting a thin highly resistantiveive UBM layer. (29.54 μΩ·cm, 295.4 μΩ·cm, 1477 μΩ·cm, 2954 μΩ‘·cm, 14770 μΩ·cm) It was found that the current crowding effect in the solder regime bump couldan be successfully relieved successfully in the solder joints with the thick Cu UBM or with the highly resistiveantive UBM. Compared to with the solder joint with Al/Ni(V)/Cu UBM, for instance, the maximum current density in a solder bump decreased dramatically by with a factor of fifteen, say from 1.11×10⁵ A/cm² to 7.54×10³ A/cm² when using a 20-μm thick Cu UBM wasis used, and it. It couldan be lowered down by a factor of seven, say to 1.55×10⁴ A/cm², when adopting a 0.7-μm UBM of 14770 μΩ·cm was adopted. Furthermore, It is worthy of notice that although a resistantiveive UBM layer wasis used, the penalty on overall resistance increase wasis negligible, since because the total resistance wasis dominated by the Al trace instead of the solder bump. (need confirmation from simulation)

FIG. 10 shows the current density distribution inside the top layer of the solder along the Z-axis in FIG. 9. The current became uniformly distributed inside the solder layer, and their maximum current densities rangeds from 7.01 to 1.55×10⁴ A/cm². Furthermore, the current distribution in the UBM, IMC layers, and in the solder bump also became more uniform when using highly resistanivetive UBM layers.

FIG. 11 is a scheme showing the IR detection apparatus 13 used. First of all, solder bump 12 was slightly milled and polished (the remaining mass is 97% of the original one), then the solder bump 12 was applied a current of 0.586 A and put on heating plate 8 to maintain a constant temperature of 70° C. The temperature distribution on the cross section was observed.

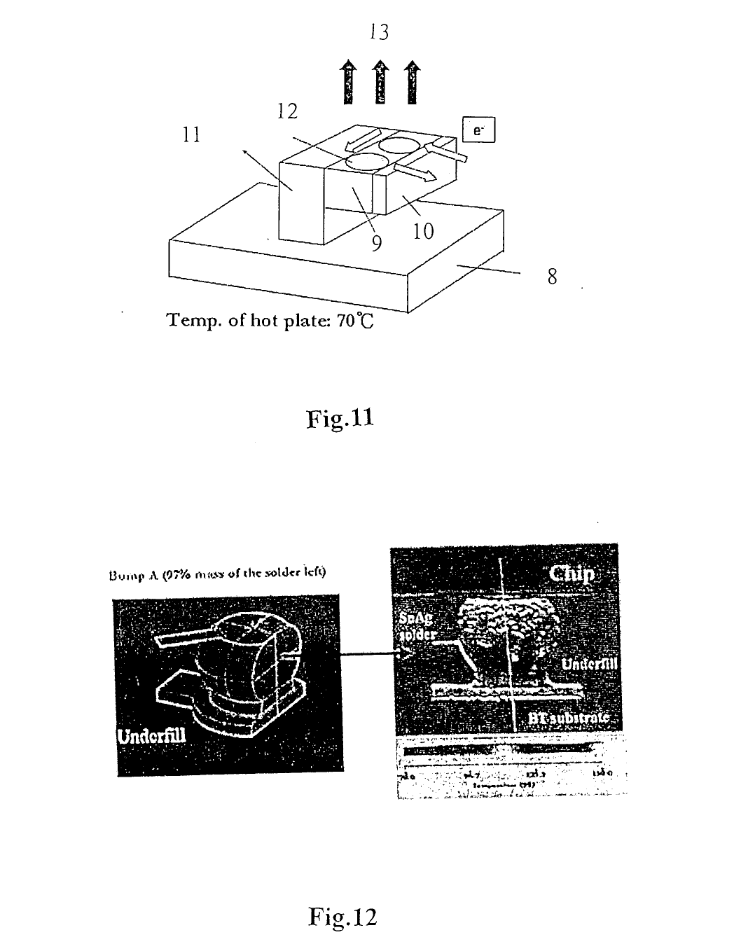

FIG. 12 shows the temperature of the whole solder bump was elevated to 54.5° C. due to Joule heating effect.

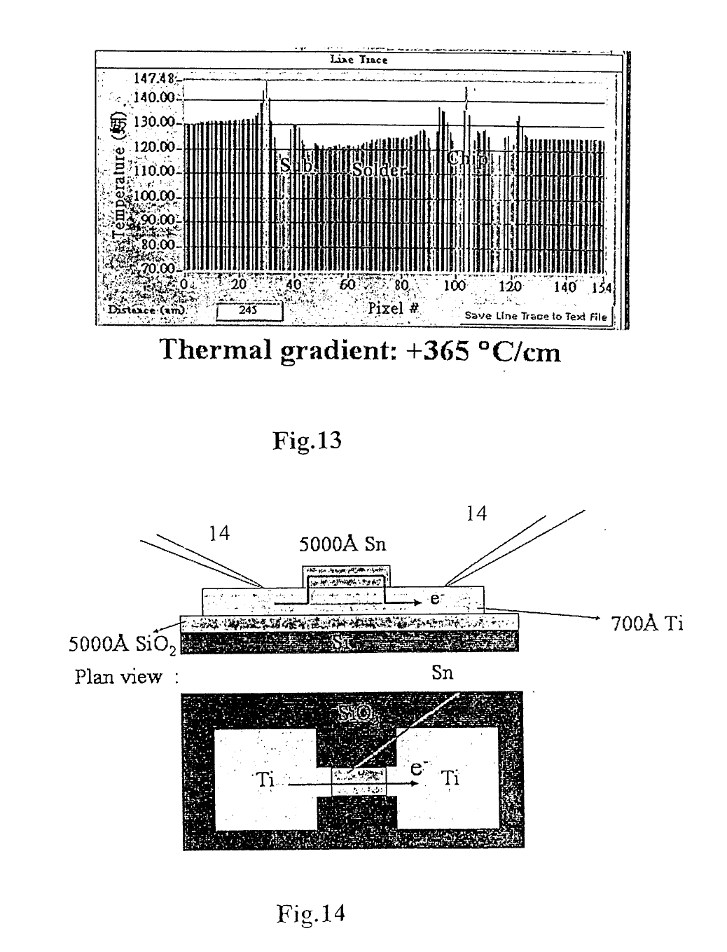

FIG. 13 shows the temperature gradient inside the solder bump was up to 365° C./cm ([temperature at chip end−temperature at substrate end]/height of the solder bump). Solder atoms were affected by heat migration under this temperature gradient to diffuse downward from the top, so that the solder bump contact at chip end was damaged to created holes.

2. The Production and Reliability of Lead-Free Solder

With the trend to use less lead, tin is becoming the main component of solders; in addition, lead frame is short generally due to the tin whisker growth created in tin layer, so that the electromigration of pure tin relates to reliability problem in lead-free solders. To observe the electromigration phenomenon of pure tin, lithographic etch technology is utilized to vapor-deposit 5,000 Å of tin film on a test sheet above 700 Å of titanium film for an electromigration study on pure tin.

FIG. 14 are an elevation and a side view of the pure test sheet in the experiment, the current density used was 1.5×10⁵ A/cm².

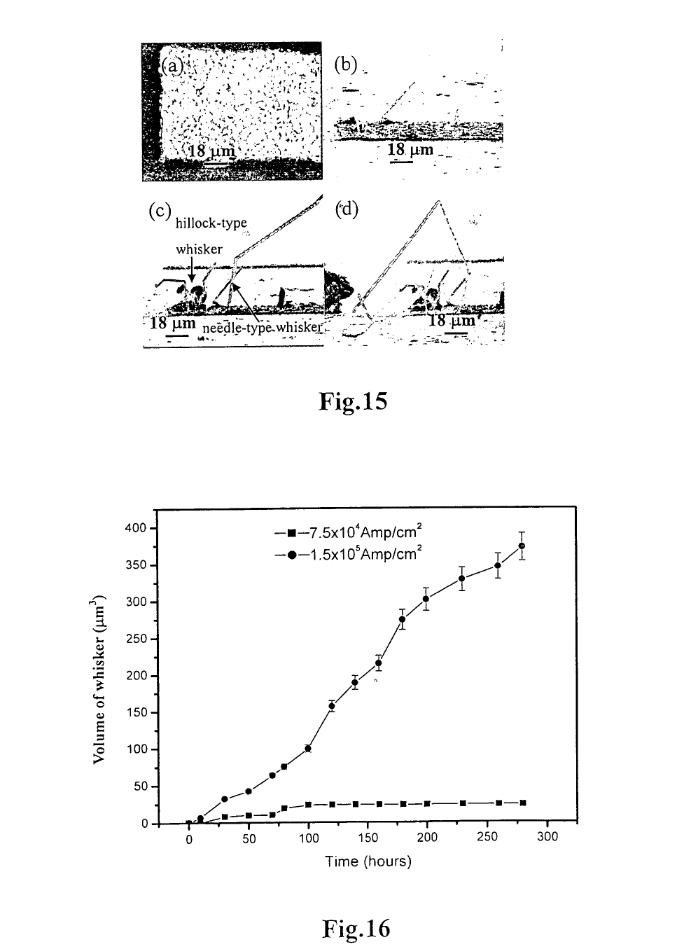

FIG. 15 are electronic microscopic images showing tin whiskers and protrusions created at anode part after applied current for time periods 0 hour, 50 hours, 160 hours, and 260 hours. It can be found that the length and amount of the tin whiskers increased as time period increased.

FIG. 16 is a graph showing the volume of tin whiskers vs. time. It can be found that the growth rate of the tin whiskers is about 3 Å/sec at room temperature when current density was 1.5×10⁵ A/cm².

### DESIGNATION OF MAIN COMPONENTS

1 Aluminum atoms
1 Silicon chips
3 Solder bump
4 Substrate
5 Aluminum lead
6 Cupper line
7 Passivation layer
8 Hot plate
9 Underfill
10 Chip
11 Board
12 Bump
13 IR detector
14 Probe

We claim:

1. A process for protecting solder joints comprising forming an UBM or pad metallurgy in solder joints and then further forming a small solder bump on UBM or pad metallurgy between substrate and chip, characterized in high electric resistance material is coated at the ends of UBM or inserted into as one layer of UBM, or pad metallurgy where substrate is connected to the solder bump, as to equalize the current distribution of solder bump, therefore the electromigration resistance of solder joints is improved by suppressing the current crowding and joule heating phenomenon.

2. The process as described in claim 1, wherein the solder is lead-free bump material.

3. The process as described in claim 1, wherein the joint includes flip-chip solder joints, anisotropic conductive film or tape automatic bond (TAB) joints.

4. The process as described in claim 1, wherein the high resistance material, in terms of UBM or pad metallurgy, is selected from solder- or process-compatible materials.

5. The process as described in claim 4, wherein the high resistance material is one of a very thin layer of pure molybdenum, oxide such as SiO₂ and Si₃N₄, or metal oxides such as Al₂O₃, metal nitride materials such as TiN and TaN.

6. A solder joint structure with UBM or pad metallurgy contained between substrate and chip for suppressing the damage by electromigration and Joule heating effect, characterized in high electric resistance material is contained at UBM or pad metallurgy, or the end location connecting UBM or pad metallurgy and chip or substrate.

7. The solder joint structure as described in claim 6, wherein the solder is lead-free bump material.

8. The solder joint structure as described in claim 6, wherein the joint includes flip-chip solder joints, anisotropic conductive film or tape automatic bond (TAB) joints.

9. The solder joint structure as described in claim 6, wherein the high resistance material, in terms of UBM or pad metallurgy, is selected from solder- or process-compatible materials.

10. The solder joint structure as described in claim 9, wherein the high resistance material is one of a very thin layer of pure molybdenum, oxide as SiO₂ and Si₃N₄, or metal oxides as Al₂O₃, metal nitride materials as TiN and TaN.
